(19) United States
(12) Patent Application Publication
(10) Pub. No.: US 2008/0203950 A1
(43) Pub. Date: Aug. 28, 2008

(54) Drive unit

(76) Inventor: Ryuichi Yoshida, Osaka (JP)

Correspondence Address: BRINKS HOFER GILSON & LIONE, P.O. BOX 10395, CHICAGO, IL, 60610, US

(21) Appl. No.: 12/072,294

(22) Filed: Feb. 25, 2008

(30) Foreign Application Priority Data
Feb. 27, 2007 (JP) 2007-046782

(51) Int. Cl. H01L 41/04

(52) U.S. Cl. 318/116

(57) ABSTRACT

The drive unit, being small in drive noise, includes an electromechanical transducer element 5, a vibrating member 6, a frictional engagement member 7, and a drive circuit 4 which is enabled to apply either a periodic main drive voltage that allows the frictional engagement member 7 to be slidingly displaced, or a periodic sub drive voltage that allows the frictional engagement member 7 to be slidingly displaced at a speed slower than that of the main drive voltage, to the electromechanical transducer element 5, wherein the drive circuit 4 applies the sub drive voltage to the electromechanical transducer element 5 during at least part of a time period of 25 msec counted from a drive start or a drive end of the frictional engagement member 7.

This application is based on application No. 2007-046782 filed in Japan, the contents of which are hereby incorporated by reference.

### BACKGROUND OF THE INVENTION

The present invention relates to a friction-drive type drive unit.

There is publicly known a friction-drive type drive unit in which a shaft-like vibrating member is reciprocatively displaced asymmetrically in its axial direction by an electromechanical transducer element such as a piezoelectric element so that a frictional engagement member frictionally engaged with the vibrating member is slidingly displaced relative to the vibrating member (which may be done in two modes that the frictional engagement member is moved and that the vibrating member is moved). JP2001-211669A discloses a circuit for applying a rectangular-wave drive voltage to expand and contract an electromechanical transducer element asymmetrically.

Although a friction-drive type drive unit is excellent in responsivity and capable of giving large driving torque to a driven member, which is an object to be driven, yet the movement of the center of gravity of the driven member may be delayed behind a sliding displacement of the frictional engagement member because of flexure of the driven member or the like. Such delay of the movement of the center of gravity of the driven member could cause the driven member to be vibrated.

As an example, FIG. 7 shows time variations of the moving speed of the centers of gravity of the frictional engagement member and the driven member resulting when the driven member is driven by a conventional friction-drive type drive unit. As seen in the figure, when the drive unit is started up, the frictional engagement member immediately reaches a predetermined drive speed. However, the driven member is accelerated with delay to the frictional engagement member so that differences between the frictional engagement member and the driven member are accumulated as elastic energy, causing the driven member to be vibrated. A vibration cycle period of the driven member depends on its natural frequency.

When the natural frequency of the driven member is in the audio range of 20 Hz to 20 kHz, vibrations of the driven member propagate as acoustic wave vibrations so as to be perceived as drive noise. Reduction of such drive noise is expected also for silencing of equipment using the drive unit.

### SUMMARY OF THE INVENTION

In view of the above and other issues, an object of the present invention is to provide a drive unit which is smaller in drive noise.

In order to achieve the above object, according to the present invention, there is provided a drive unit comprising: an electromechanical transducer element which expands and contracts with a voltage applied thereto; a vibrating member one end of which is fixed to the electromechanical transducer element, and which can be reciprocatively displaced in an axial direction by expansion and contraction of the electromechanical transducer element; a frictional engagement member which is frictionally engaged with the vibrating member, and which can be slidingly displaced relative to the vibrating member by reciprocative movement of the vibrating member; and a drive circuit which is enabled to apply either a periodic main drive voltage that allows the frictional engagement member to be slidingly displaced, or a periodic sub drive voltage that allows the frictional engagement member to be slidingly displaced at a speed slower than that of the main drive voltage, to the electromechanical transducer element, wherein the drive circuit applies the sub drive voltage to the electromechanical transducer element during at least part of a time period of 25 msec counted from a drive start or a drive end of the frictional engagement member.

In this drive unit, in a case where the driven member driven by the drive unit has a natural vibration period of 50 msec or lower and generates vibrations in audio frequencies of 20 Hz or higher, by the setting that vibration energy accumulated due to delay of the driven member to a rising edge of the frictional engagement member upon application of the main drive voltage and vibration energy accumulated due to delay of the driven member upon application of the sub drive voltage are set different in phase from each other, the two kinds of vibration energy are canceled out, so that the resulting vibrations can be reduced.

Also, in equipment to which a small-size, friction-drive type drive unit is applied, since the natural frequency of the driven member or the casing or the like is typically 100 Hz to 1 kHz, the sub drive voltage may well be applied for a period not less than 125 μsec and not more than 5 msec.

Also in the drive unit of the invention, it is preferable that at a drive start, the sub drive voltage is started to be applied, or that the main drive voltage is first applied and subsequently the sub drive voltage is applied.

Further, in the drive unit of the invention, it is also preferable that the sub drive voltage is applied divisionally a plurality of times, where a ratio of an application time period of the sub drive voltage to an application time period of the main drive voltage is decreased stepwise. The speed of the frictional engagement member is decreased at a plurality of timings at which the driven member accumulates elastic energy in its vibrations with delay to the driving direction, by which the delay of the driven member is reduced, thus allowing the vibration energy to be reduced little by little. The application time of the sub drive voltage is decreased in response to the vibration energy, making driving torque to be delayed excessively, by which accumulation of the elastic energy in the forward direction can be prevented.

Also in the drive unit of the invention, preferably, the drive circuit is a full bridge circuit including a pair of charge switching elements which respectively allow a pair of electrodes of the electromechanical transducer element to be connected to power supply, and a pair of discharge switching elements which respectively allow the pair of electrodes to be grounded, and the sub drive voltage is generated by nullifying operations of the charge switching elements and the discharge switching elements connected to any one of the electrodes of the electromechanical transducer element.

Also, in the drive unit of the invention, setting the main drive voltage and the sub drive voltage equal in frequency to each other makes the control easier to fulfill. For example, the sub drive voltage may be a voltage having a waveform resulting from compressing a wave height of the main drive voltage. Also, the main drive voltage and the sub drive voltage may be both rectangular-wave voltages that differ from each other only in duty ratio.

Also, the sub drive voltage may be either a voltage having a waveform that allows the frictional engagement member to be moved in a direction opposite to that of the main drive voltage, or a no-voltage signal.

According to the present invention, since the drive speed of the drive unit is decreased in response to a delay of equipment to be used or a member to be driven by the drive unit, accumulation of vibration energy in the audio range can be reduced.

### BRIEF DESCRIPTION OF THE DRAWINGS

These and other objects and features of the present invention will become apparent from the following description taken in conjunction with the preferred embodiments thereof with reference to the accompanying drawings, in which:

FIG. 1 is a schematic diagram showing a drive unit according to a first embodiment of the invention;

FIG. 2 is a chart showing speed variations resulting when the drive unit of FIG. 1 is driven in a pattern of a prior art;

FIG. 3 is a chart showing speed variations resulting when the drive unit of FIG. 1 is driven in a pattern of the invention;

FIG. 4 is a chart showing speed variations resulting when the drive unit of FIG. 1 is driven in a different pattern;

FIG. 5 is a chart showing speed variations resulting when the drive unit of FIG. 1 is driven in another different pattern;

FIG. 6 is a schematic diagram showing a drive unit according to a second embodiment of the invention; and

FIG. 7 is a chart showing drive speed variations in a drive unit according to a prior art.

### DETAILED DESCRIPTION OF THE PREFERRED EMBODIMENTS

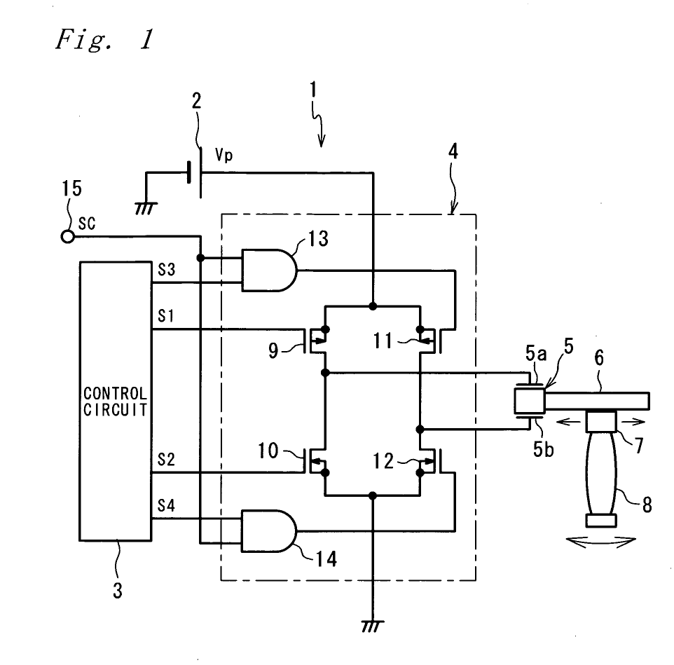

FIG. 1 shows a construction of a drive unit 1 according to a first embodiment of the invention. The drive unit 1 has a drive circuit 4 to which a DC power supply 2 of a voltage Vp (V) and a control circuit 3 are connected, a piezoelectric element (electromechanical transducer element) 5 to electrodes 5a, 5b of which an output of the drive circuit 4 is applied, a shaft-like vibrating member 6 whose one end is fixed to the piezoelectric element 5, and a frictional engagement member 7 to be engaged with the vibrating member 6 by frictional force. The drive unit 1 is a lens drive unit in which the piezoelectric element 5 is fixed to its casing and the frictional engagement member 7 holds a lens (driven member) 8.

The piezoelectric element 5 is so designed as to expand and contract in an axial direction of the vibrating member 6 in response to a voltage applied to between the electrodes 5a, 5b. Expansion and contraction of the piezoelectric element 5 causes the vibrating member 6 to be reciprocatively moved in the axial direction. When the vibrating member 6 slowly moves, the frictional engagement member 7 moves along therewith as it keeps frictionally engaged with the vibrating member 6. When the vibrating member 6 moves abruptly, the frictional engagement member 7 tends to stay as it is by its inertia force, resulting in a sliding move on the vibrating member 6. Thus, the drive unit 1 can achieve a positioning of the lens 8 relative to the casing.

The drive circuit 4 includes transistors 9, 10, 11, 12 and AND gate devices 13, 14. The transistor 9 is a charge switching element implemented by a p-channel FET which, when turned on, applies a voltage of the power supply 2 to the electrode 5a of the piezoelectric element 5, and the transistor 10 is a discharge switching element implemented by an n-channel FET which, when turned on, makes the electrode 5a grounded. The transistor 11 is a charge switching element implemented by a p-channel FET which, when turned on, applies a voltage of the power supply 2 to the electrode 5b, and the transistor 12 is a discharge switching element implemented by an n-channel FET which, when turned on, makes the electrode 5b grounded.

The control circuit 3 outputs periodically rectangular-wave control signals S1, S2, S3, S4 for driving the transistors 9, 10, 11, 12, respectively, where the control signal S1 and the control signal S1 are of an identical waveform while the control signal S3 and the control signal S4 are inverted outputs of the control signals S1, S2, respectively. With a voltage signal sc applied to an external terminal 15, the AND gate devices 13, 14 apply the control signals S3, S4 to the transistors 11, 12, respectively. On the other hand, with no voltage signal sc applied to the external terminal 15, the AND gate devices 13, 14 continue to output LO signals independently of the control signals S3, S4, keeping the transistor 11 in an off state and the transistor 12 in an on state.

When the voltage signal sc is applied to the external terminal 15, in the drive circuit 4, the transistor 9 and the transistor 12 are simultaneously turned on. The transistor 10 and the transistor 11 are turned on while the transistors 9, 12 are in the off state. That is, the drive circuit 4 is a full bridge circuit that applies a main drive voltage, which is a rectangular wave having an amplitude 2 Vp (V), to the piezoelectric element 5 by applings the voltage Vp (V) of the power supply 2 to either one of the electrodes 5a, 5b of the piezoelectric element 5 while making the other grounded, and alternately switching over between the electrodes 5a, 5b be applied the voltage Vp (V).

Turn-on and -off operations at a specified time ratio are iterated with a constant frequency of the control signals S1, S2, S3, S4. For example, the control signals S1, S2 have an on/off ratio of 0.7:0.3 at a frequency of 140 kHz. In this case, a main drive voltage with a frequency of 140 kHz, an amplitude 2 Vp (V) and a duty ratio of 0.7 is applied to between the electrodes 5a-5b of the piezoelectric element 5.

Then, in this case, because of mechanical delay of the piezoelectric element 5 and the vibrating member 6, the vibrating member 6 is abruptly pulled out and slowly pulled back by the piezoelectric element 5, thus making the frictional engagement member 7 slidingly moved on the vibrating member 6 toward the piezoelectric element 5. Reversing output time ratios of the control signals S1, S2 to the control signals S3, S4 results in output of a main drive voltage that makes the frictional engagement member 7 slidingly moved farther away from the piezoelectric element 5.

With no voltage signal sc applied to the external terminal 15, the drive circuit 4 is a half bridge circuit that normally holds the electrode 5b of the piezoelectric element 5 normally grounded and that makes the electrode 5a connected alternately to the power supply 2 and the grounding point so that a sub drive voltage, which is a rectangular wave (with its wave height compressed) having an amplitude Vp (V) being a half of the main drive voltage, is applied to the piezoelectric element 5. This sub drive voltage is smaller in amplitude than the main drive voltage, resulting in a smaller expansion-and-contraction length difference of the piezoelectric element 5, so that the moving speed of the frictional engagement member 7 becomes about half that of the main drive voltage.

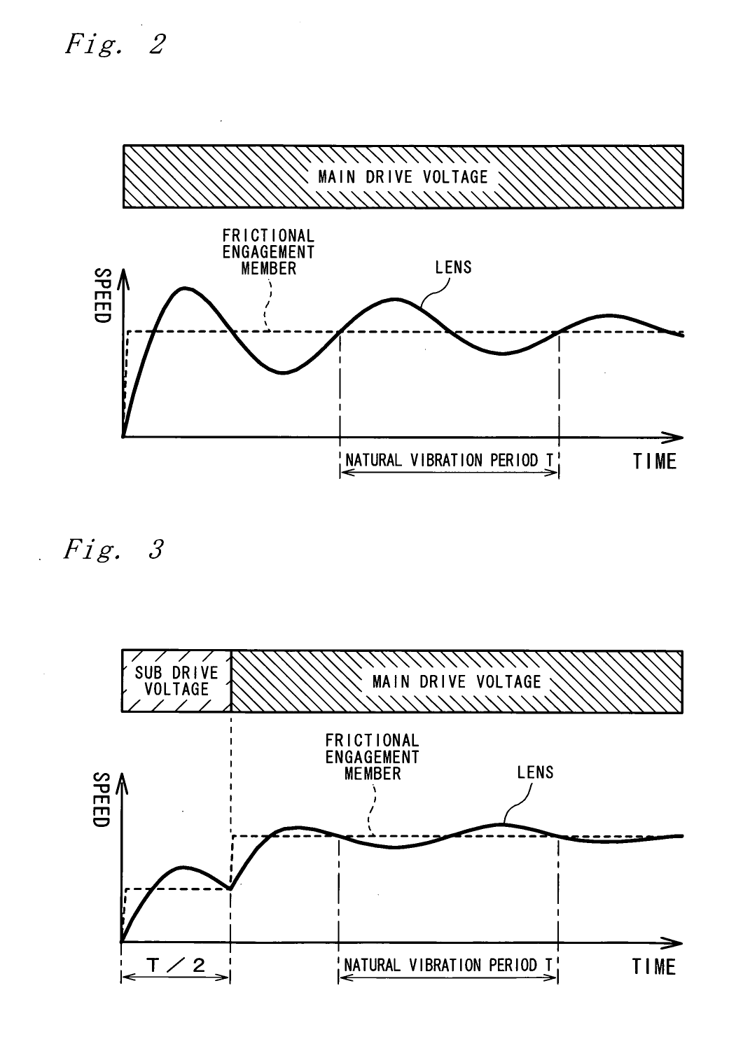

FIG. 2 shows a relationship between an output of the drive circuit 4 and moving speeds of the frictional engagement member 7 and the lens 8 upon a drive start of the drive unit 1. As shown in the figure, when the main drive voltage alone is applied to the piezoelectric element 5, the frictional engagement member 7 rises immediately upon the drive start, moving at a constant speed. However, the lens 8 flexes and swings about the frictional engagement member 7 as shown in FIG. 1, so that the center of gravity of the lens 8 is accelerated with delay to the frictional engagement member 7 as shown in FIG. 2. Elastic energy accumulated by the flexures of the lens 8 results in energy that causes the lens 8 to be vibrated on the frictional engagement member 7. The cycle period of the vibrations is the natural vibration period T of the lens 8, and their amplitude gradually damps as the energy dissipates as aerial vibrations or heat.

In the drive unit 1 of this embodiment, as shown in FIG. 3, upon a drive start of the drive unit 1, the voltage signal of the external terminal 15 is first turned off so that the sub drive voltage is applied to the piezoelectric element 5, and after the sub drive voltage has been continued to be applied by a half of the natural vibration period T, a voltage signal is inputted from the external terminal 15 so that the main drive voltage is applied to the piezoelectric element 5.

As shown above, applying the sub drive voltage in the beginning causes the moving speed of the frictional engagement member 7 to be slow, so that the quantity of delay of the lens 8 to the frictional engagement member 7 becomes smaller upon a drive start. That is, the elastic energy accumulated on the lens 8 becomes smaller, so that the amplitude of vibrations of the lens 8 becomes smaller.

In this embodiment, the sub drive voltage is kept applied for a duration time 1/2 T, followed by switching to the main drive voltage. At this time point, the lens 8 is positioned at a lead ahead of the frictional engagement member 7 due to the vibrations, where the main drive voltage is applied so that the frictional engagement member 7 is accelerated, causing the lens 8 to be delayed. That is, when the delay in the application of the sub drive voltage is turned into a lead by vibrations, this delay is canceled out by a delay caused by the application of the main drive voltage, by which the elastic energy accumulated in the lens 8 is finally diminished.

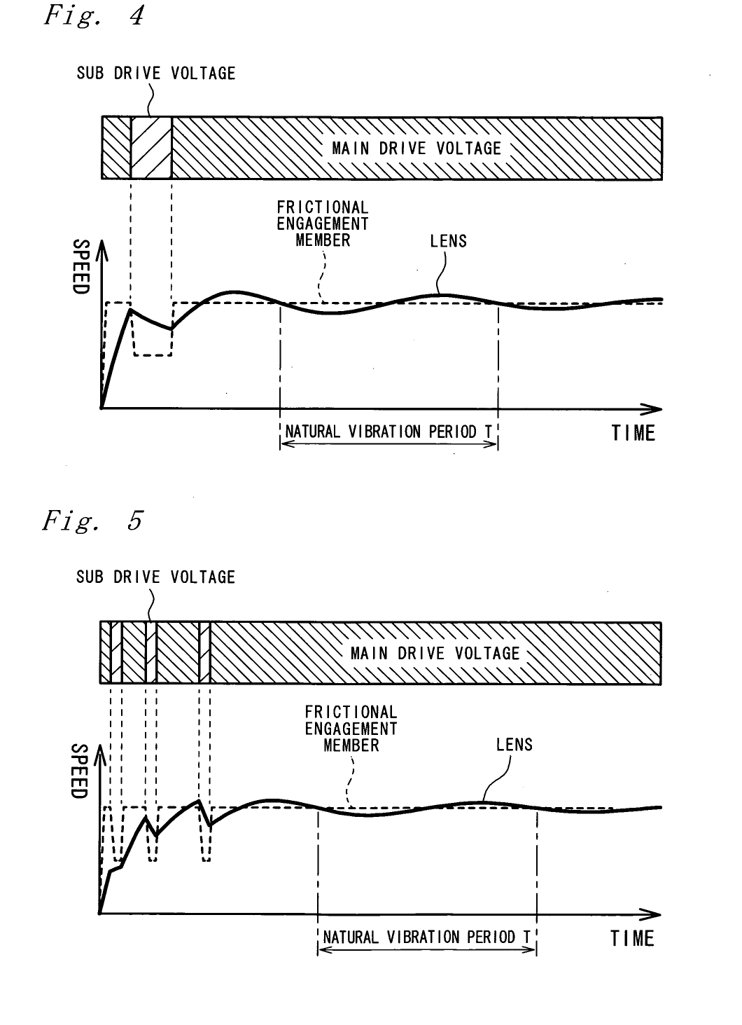

Also in this embodiment, as shown in FIG. 4, it is also allowable that the main drive voltage is first applied to the piezoelectric element 5 and thereafter the sub drive voltage is kept applied to the piezoelectric element 5 for a specified time period while the lens 8 remains delayed behind the frictional engagement member 7.

By the operational process that the main drive voltage is first applied to make the frictional engagement member 7 accelerated and thereafter the sub drive voltage is once applied to make the frictional engagement member 7 decelerated, it becomes achievable to reduce the delay of the lens 8 and thereby reduce the accumulation quantity of vibration energy, so that the vibrations of the lens 8 can be suppressed.

According to this drive pattern, as compared with the drive pattern of FIG. 3, the application time of the sub drive voltage is shorter and so the moving speeds of the frictional engagement member 7 and the lens 8 are less decreased.

However, because the main drive voltage and the sub drive voltage are required to give vibration energy to the lens 8 in mutually different phases in order to reduce the elastic energy to be accumulated in the lens 8, the application time of the sub drive voltage is desirably set to 1/8 or more of the natural vibration period T.

It is also allowable, as shown in FIG. 5, that the sub drive signal is applied a plurality of times during a 1/2 period of the natural vibration period T of the lens 8 starting from a drive start. In this case, with a view to canceling out the vibration energy attributed to the main drive signal, increasing the ratio of application time of the sub drive voltage at first and then decreasing stepwise the application ratio of the sub drive voltage in response to decreases of the vibration energy due to the main drive signal makes it possible to effectively suppress the vibrations of the lens 8.

It is not necessarily easy to predict the natural vibration period T of the lens 8. However, if the natural vibration period T of the lens 8 falls outside a range of 0.05 to 50 msec, which corresponds to the audio range (20 Hz-20 kHz), then vibrations of the lens 8, if involved, are not perceived as noise. Therefore, the drive unit 1 may well be designed so that the sub drive voltage is applied during a period of 25 msec from a drive start or a drive end, given that the natural vibration period T of the lens 8 falls within the audio range.

Further, vibrations of the lens 8 propagate outside via the equipment casing in which the drive unit 1 and the lens 8 are housed. Since the casing for portable equipment or the like typically has a natural vibration period of 1 to 10 msec, it is effective that the sub drive voltage is applied for a period being not less than 125 μsec, which is 1/8 of 1 msec, and being not more than 5 msec, which is 1/2 of 10 msec.

The drive pattern for starting to drive the lens 8 by the drive unit 1 has been described hereinabove. However, also for stoppage of the lens 8 that is in a moving state, stopping the main drive voltage before applying the sub drive voltage during the period of 1/2 T makes it possible to reduce vibrations of the lens 8 upon a stop, as in the case of a drive start.

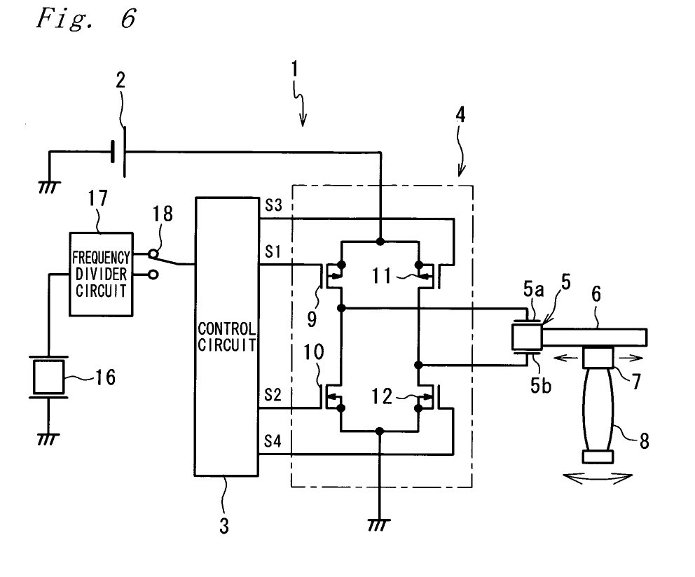

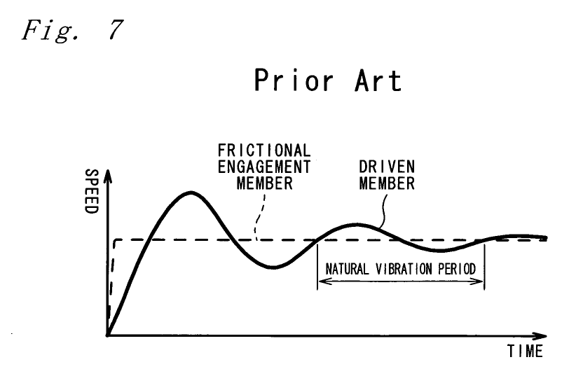

FIG. 6 shows a drive unit 1 according to a second embodiment of the invention. Like constituent members as in the first embodiment are designated by like numerals and their description is omitted. The drive unit 1 has an oscillator 16 for generating pulses of, e.g., 20 MHz, a frequency divider circuit 17 for extracting pulses of 20 MHz and pulses of 10 MHz from the pulses generated by the oscillator 16, and a selector switch 18 for selecting an output for the frequency divider circuit to provide an input as an operation clock for the control circuit.

In this embodiment, when an operating clock signal of 20 MHz is inputted to the control circuit 3 by the selector switch 18, the drive circuit 4 outputs the main drive voltage. When an operating clock signal of 10 MHz is inputted to the control circuit 3, the number of times of expansion and contraction of the piezoelectric element 5 is reduced to half that of the application of the main drive voltage, so that the drive circuit 4 outputs a sub drive voltage that causes the moving speed of the frictional engagement member 7 to be reduced by half.

In this embodiment also, applying the sub drive voltage to the piezoelectric element 5 in patterns shown in FIGS. 3 to 5 makes it possible to suppress vibrations of the lens 8.

Further, for the present invention, the sub drive voltage may also be a voltage that differs from the main drive voltage only in duty ratio. For example, given that the duty ratio of the main drive voltage is 0.7, setting the duty ratio of the sub drive voltage to 0.85 causes the moving speed of the frictional engagement member 7 by the sub drive voltage to be reduced to half that in the application of the main drive voltage.

As shown above, with the setting that the main drive voltage and the sub drive voltage are rectangular-wave voltages that differ from each other only in duty ratio, the main drive voltage and the sub drive voltage can be switched over only by changing the set value that determine the duty ratio of the control circuit 3, hence the control being easy to fulfill.

Furthermore, although the sub drive signal in the invention may be any one that allows the frictional engagement member 7 to be moved at a moving speed slower than that of the main drive voltage, yet such sub drive signals include those that cause the speed to be zero or negative values. In conclusion, the sub drive signal may be either a null signal or an inverse-directed drive voltage. Therefore, it is to be noted that various changes and modifications are apparent to those skilled in the art. Such changes and modifications are to be understood as included within the scope of the present invention as defined by the appended claims unless they depart therefrom.

What is claimed is:

1. A drive unit comprising:
an electromechanical transducer element which expands and contracts with a voltage applied thereto;
a vibrating member one end of which is fixed to the electromechanical transducer element, and which can be reciprocatively displaced in an axial direction by expansion and contraction of the electromechanical transducer element;
a frictional engagement member which is frictionally engaged with the vibrating member, and which can be slidingly displaced relative to the vibrating member by reciprocative movement of the vibrating member; and
a drive circuit which is enabled to apply either a periodic main drive voltage that allows the frictional engagement member to be slidingly displaced, or a periodic sub drive voltage that allows the frictional engagement member to be slidingly displaced at a speed slower than that of the main drive voltage, to the electromechanical transducer element, wherein
the drive circuit applies the sub drive voltage to the electromechanical transducer element during at least part of a time period of 25 msec counted from a drive start or a drive end of the frictional engagement member.

2. The drive unit as claimed in claim 1, wherein the sub drive voltage is applied for a period not less than 125 μsec and not more than 5 msec.

3. The drive unit as claimed in claim 1, wherein the sub drive voltage is started to be applied at a time of a drive start or a drive end.

4. The drive unit as claimed in claim 1, wherein at a drive start, the main drive voltage is first applied and subsequently the sub drive voltage is applied.

5. The drive unit as claimed in claim 1, wherein the sub drive voltage is applied divisionally a plurality of times, where a ratio of an application time period of the sub drive voltage to an application time period of the main drive voltage is decreased stepwise.

6. The drive unit as claimed in claim 1, wherein
the drive circuit is a full bridge circuit including a pair of charge switching elements which respectively allow a pair of electrodes of the electromechanical transducer element to be connected to power supply, and a pair of discharge switching elements which respectively allow the pair of electrodes to be grounded, and
the sub drive voltage is generated by nullifying operations of the charge switching elements and the discharge switching elements connected to any one of the electrodes of the electromechanical transducer element.

7. The drive unit as claimed in claim 1, wherein the sub drive voltage is a voltage having a waveform resulting from compressing a wave height of the main drive voltage.

8. The drive unit as claimed in claim 1, wherein the sub drive voltage is a voltage having a waveform that allows the frictional engagement member to be slidingly displaced in a direction opposite to that of the main drive voltage.

9. The drive unit as claimed in claim 1, wherein the sub drive voltage is a voltage having a waveform that allows the frictional engagement member to be slidingly displaced at a speed about half that of the main drive voltage.

10. The drive unit as claimed in claim 1, wherein the main drive voltage and the sub drive voltage are both rectangular-wave voltages that differ from each other only in duty ratio.
